(19) United States
(12) Patent Application Publication
(10) Pub. No.: US 2009/0039922 A1
(43) Pub. Date: Feb. 12, 2009

(54) Multi-level comparator for fix power consumption

(75) Inventors: Ying-Hsiang WANG, Taoyuan (TW); Wen-Yaw CHUNG, Taoyuan (TW); Chiung-Cheng CHUANG, Taoyuan (TW); Chien-Yi KAO, Taoyuan (TW)

Correspondence Address: WPAT, PC, 7225 BEVERLY ST., ANNANDALE, VA, 22003, US

(73) Assignee: CHUNG YUAN CHRISTIAN UNIVERSITY, Taoyuan (TW)

(21) Appl. No.: 12/057,483

(22) Filed: Mar. 28, 2008

(30) Foreign Application Priority Data
Aug. 7, 2007 (TW) 096128951

(51) Int. Cl. H03K 5/22

(52) U.S. Cl. 327/76

(57) ABSTRACT

A multi-level comparator with fixed power consumption is disclosed. By using the switch character of differential pair and parallelizing single side of common source amplifier with multi-level input, the power of the multi-level comparator can be fixed by the current bias. This result shows that the multi-level comparator is able to heighten input stages at fixed power. Therefore, the multi-level comparator has the functionalities of several different comparators while maintaining fixed power consumption.

### BACKGROUND OF THE INVENTION

1. Field of the Invention

The present invention generally relates to a multi-level comparator, especially to a multi-level comparator with fixed power consumption.

2. Description of the Prior Art

In modern circuits and systems, such as digital-analog signal transformation, power management, vital sign monitoring . . . so on and so forth, multiple comparators are often required for the purpose of signal identification and processing due to increasing system complexity. This leads to a higher system power consumption, therefore limiting the application of such system in portable devices. The present invention discloses a multi-level comparator with fixed power consumption which incorporates several comparators in one unit that is powered by a single power source, thereby fixing the static power consumption and reducing overall power consumption as well as the area needed.

Referring to FIG. 1, for a conventional system, to compare multiple voltage level inputs using a single input source, a plurality of comparators are required. The more voltage levels to be compared, the higher system power loss is, leading to a shorter battery life for a portable device.

Researchers have been working on multiple level input comparators, for example Guo, Y. B.; Current, K. W., “Voltage comparator circuits for multiple-valued CMOS logic”, ISMVL 2002. Proceedings 32nd IEEE International Symposium on 15-18 May 2002 Page(s):67-73, and Hsia, S.-C.;, “High-speed multi-input comparator”, Circuits, Devices and Systems, IEE Proceedings-Volume 152, Issue 3, 3 Jun. 2005 Page(s):210-214. These comparators are mostly carried out in the form of digital circuit, the advantages thereof include:
1. Acceptable voltage range for the input is limited by the critical voltage of the transistors and the power source;
2. Connecting the input of comparator to the source or drain of the transistor could result in the load effect;
3. The clock generator is required, which would cause additional noise, additional power loss and a larger area; and
4. Multiple transistors or logic gates are required, leading to a larger area.

To overcome the above issues, the present invention discloses a multiple level comparator using the analog circuit. The disclosed comparator uses the gate of a transistor as the input point.

### SUMMARY OF THE INVENTION

Therefore, in accordance with the previous summary, objects, features and advantages of the present disclosure will become apparent to one skilled in the art from the subsequent description and the appended claims taken in conjunction with the accompanying drawings.

### BRIEF DESCRIPTION OF THE DRAWINGS

The accompanying drawings incorporated in and forming a part of the specification illustrate several aspects of the present invention, and together with the description serve to explain the principles of the disclosure. In the drawings:

FIG. 1 is a schematic of a multi-level comparator in accordance with the prior art;

FIG. 2 is a multi-level comparator in accordance with one embodiment of the present invention;

FIG. 3 is a multi-level comparator in accordance with another embodiment of the present invention;

FIG. 4 is a multi-level comparator in accordance with yet another embodiment of the present invention; and

FIG. 5 is a performance simulation of a disclosed 5-level comparator.

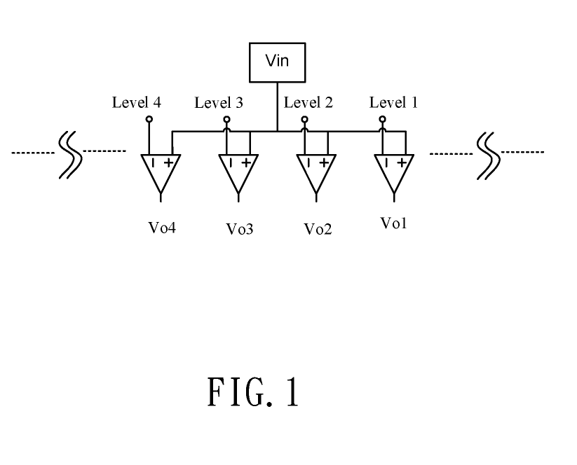

### DETAILED DESCRIPTION OF THE PREFERRED EMBODIMENTS

The present disclosure can be described by the embodiments given below. It is understood, however, that the embodiments below are not necessarily limitations to the present disclosure, but are used to a typical implementation of the invention.

Having summarized various aspects of the present invention, reference will now be made in detail to the description of the invention as illustrated in the drawings. While the invention will be described in connection with these drawings, there is no intent to limit it to the embodiment or embodiments disclosed therein. On the contrary the intent is to cover all alternatives, modifications and equivalents included within the spirit and scope of the invention as defined by the appended claims.

It is noted that the drawings presents herein have been provided to illustrate certain features and aspects of embodiments of the invention. It will be appreciated from the description provided herein that a variety of alternative embodiments and implementations may be realized, consistent with the scope and spirit of the present invention.

It is also noted that the drawings presents herein are not consistent with the same scale. Some scales of some components are not proportional to the scales of other components in order to provide comprehensive descriptions and emphasizes to this present invention.

One objective of the present invention is to provide a multi-level comparison device. The provided comparator comprises an input circuit and a plurality of comparison circuits. The input circuit and each comparison circuit comprise a pair of transistors in series that are a first transistor and a second transistor, respectively. Each of the first and second transistor comprises a first electrode, a second electrode and a third electrode, wherein for all the series transistors, the third electrode of the first transistor is electrically coupled with the first electrode of the second transistor; the first electrode of all first transistors are in parallel with a first electrical connection point; the third electrode of all second transistors are in parallel with a second electrical connection point; the second electrode of the first transistor in each comparison circuit is coupled with a comparison signal; the third electrode of the first transistor in each comparison circuit outputs an output signal, where the third electrode of each first transistor can be in series with two inverters for outputting its output signals. The second electrode of the first transistor in the input circuit is electrically coupled with an input signal. In addition, each comparison circuit can be coupled with different comparison signals.

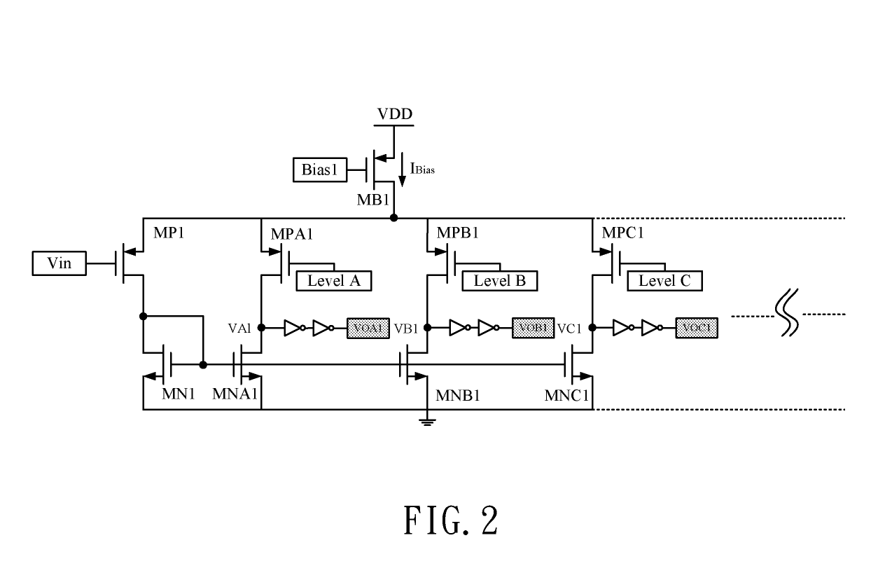

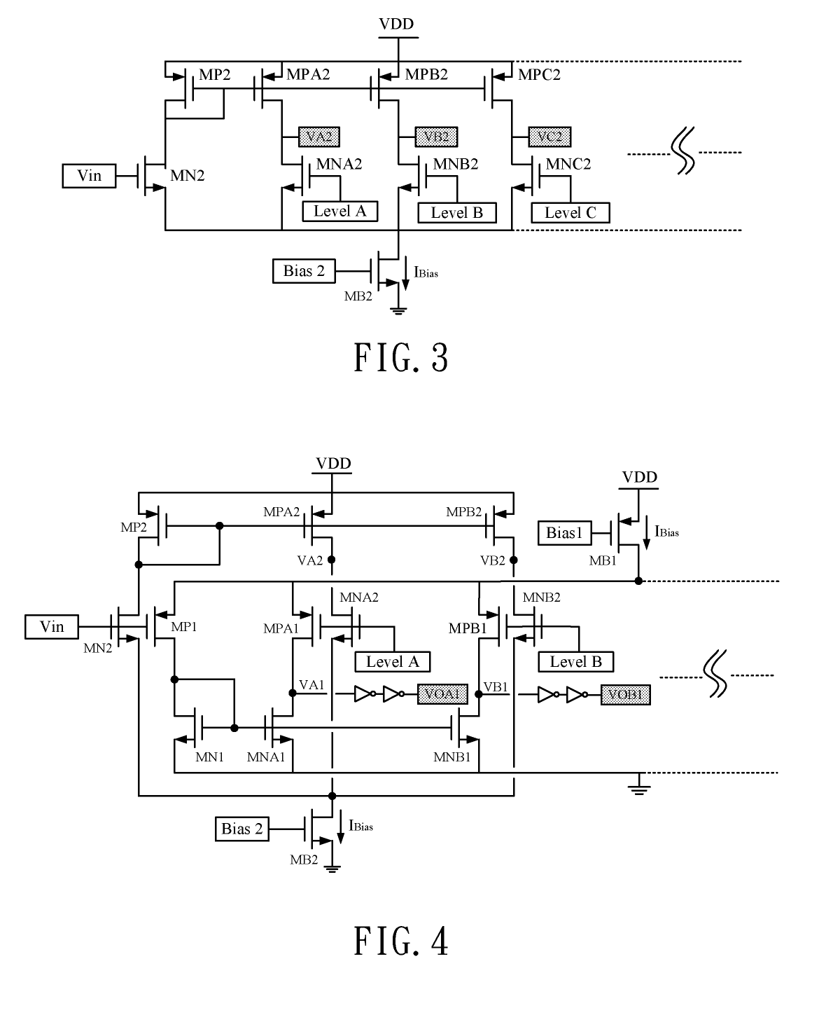

The present invention discloses a multi-level comparator which is based on the conventional analog comparator technique. Referring to FIG. 2 and 3, the present invention utilizes a differential pair switch along with a parallel single-sided amplifier to achieve the multi-level comparator architecture, wherein the input signal is Vin, the voltage to be compared is Level A, Level B, Level C . . . , and the output signal is VA, VB, VC . . . The present invention is expandable and the speed and comparison level can be adjusted on demand.

Referring to FIG. 2 and 3, the first embodiment of the present invention discloses a multi-level comparison device which comprises an input circuit and a plurality of comparison circuits. The input circuit and each comparison circuit comprise a pair of transistors in series, which are, respectively, a first transistor(MP1-MPA1-MPB1-MPC1 . . . etc. in FIG. 2, or MN2-MNA2-MNB2-MNC2 . . . etc. in FIG. 3) and a second transistor(MN1-MNA1-MNB1-MNC1 . . . etc. in FIG. 2, or MP2-MPA2-MPB2-MPC2 . . . etc. in FIG. 3). Each of the first and second transistor comprises a first electrode, a second electrode and a third electrode, wherein for all the series transistors, the third electrode of the first transistor is electrically coupled with the first electrode of the second transistor; the first electrode of all first transistors are in parallel with a first electrical connection point; the third electrode of all second transistors are in parallel with a second electrical connection point; the second electrode of the first transistor in each comparison circuit is coupled with a comparison signal(the voltage are, respectively, Level A, Level B, Level C . . . ); the third electrode of the first transistor in each comparison circuit outputs an output signal(VA1, VB1, VC1 . . . in FIG. 2, or VA2, VB2, VC2 . . . in FIG. 3), where the third electrode of each first transistor can be in series with two inverters to output its belonging output signals. The second electrode of the first transistor in the input circuit is electrically coupled with an input signal(Vin). In addition, each comparison circuit can be coupled with different comparison signals.

Referring to FIG. 2, in one preferred example of the present invention, the first transistor of the comparison circuits is formed from a P-channel metal-oxide-semiconductor field-effect transistor(MOSFET) so as to form a P-channel MOSFET multi-level comparator. In other words, the first and second transistor are a P-channel MOSFET transistor and an N-channel MOSFET transistor, respectively. The first electrical connection point is coupled with a bias circuit; the second electrical connection point is coupled with a ground circuit(GROUND)(when in a positive-negative voltage system, the second electrical connection point is electrically coupled with the negative voltage, VSS). The bias circuit can comprise a transistor(MB1), for example a P-channel MOSFET; this transistor comprises a first electrode, a second electrode and a third electrode, wherein the first electrode is electrically coupled with a power source(VDD), the second electrode with a bias signal(Bias1), and the third electrode with the first electrical connection point. The bias signal controls a bias current(IBias) between the first and third electrode. Moreover, the third electrode of the first transistor in each comparison circuit is in series with two inverters for outputting its belonging output signals (VOA1, VOA2, VOA3 . . . etc. in the figure).

Referring to FIG. 3, in another preferred example of the present invention, the first transistor of the comparison circuit is formed from an N-channel MOSFET so as to form an N-channel MOSFET multi-level comparator. In other words, the first and second transistor are an N-channel MOSFET transistor and a P-channel MOSFET transistor, respectively. The second electrical connection point is coupled with a power source(VDD) and the first electrical connection point with a bias circuit. The bias circuit can comprise a transistor(MB2), for example an N-channel MOSFET. This transistor comprises a first electrode, a second electrode and a third electrode, wherein the first electrode is electrically coupled with a ground circuit, the second electrode with a bias signal(Bias2), and the third electrode with the second electrical connection point. The bias signal controls a bias current(IBias) between the first and third electrode.

It is understood by those skilled in the art that the form of the first and second transistor is not limited and can be other transistors which control the current between the first and third electrode through the signal of the second electrode, such as MOSFET, junction field-effect transistor(JFET), bipolar junction transistor . . . etc. In addition, in the present invention, for different transistors the first and second electrical connection point will be coupled with an appropriate power source.

Referring to FIG. 2, for the purpose of circuit analysis, first assuming the input signal Vin is lower than the comparison signals Level A˜Level C. In such case, all the current are biased to the first transistor MP and at the same time mirrored to the second transistor MNA. However, because the first transistors MPA˜MPC are then off, the second transistors MNA˜MNC enter the deep triode region, leading to low outputs VA˜VC. Similarly, when the input signal Vin is higher than the comparison signals Level A and lower than Level B and C, most of the current flows into the first transistor MPA, but for first transistors MPB and MPC, input signal Vin still possesses a higher driving voltage Vov, therefore these two first transistors are then cut off and they mirror the current of second transistor MN to the cutoff region, leading to a low output VB and VC, and a high output VA.

The level of the comparator also affects the allocation of the current. For example, when the comparator is level three and all the outputs are high, the current for each branch is

Iₙ=I_{Bias}/n (1.1)

where n is the level of the comparator. And the power consumption is fixed at

Power=I_{Bias}×V_{DD} (1.2)

It can be seen from (1.1) that the current flowing through each level would self-adjust based on the number of the cascade stages. However, this leads to poorer drive for loading. In addition, in principal this structure can resist the common-mode input signal, but there will still be some following with the common-mode signal. Therefore, the present invention sets two inverters on the output end of the differential pair to overcome the above problems.

The characteristics of the disclosed comparator are similar to that of a differential pair with active current mirror:

V_{DD}_{ₘᵢₙ}=V_{SDB,sat}+V_{SDP,sat}+V_{GSN} (2.1)

ICMRₘᵢₙ=V_{GSN}−V_{Tp} (2.2)

ICMRₘₐₓ=V_{DD}−V_{SDB,sat}−V_{SGP} (2.3)

From (2.2)˜(2.3) it can be seen that the comparator in FIG. 2 is suitable for common mode inputs with a lower level. To improve this, as shown in FIG. 3, the present invention provides an additional multi-level comparator with an N-channel MOSFET as the multi-level comparator for the input of the differential pair.

Moreover, as shown in FIG. 4, the present invention also provides a rail-to-rail multi-level comparator with combined the inputs, outputs, P-channel and N-channel MOSFET multi-level comparators from FIG. 2 and FIG. 3, and whose input range is close to VDD˜GND. This system is expandable on the input level, and can transform to other types of comparator such as the multi-level comparator with hysteresis, by modifying part of the circuits.

Referring to FIG. 4, the second embodiment of the present invention discloses a multi-level comparator which comprises an input signal connection point, a first multi-level comparison device with fixed power consumption and a second multi-level comparison device with fixed power consumption. The input signal connection point receives an input signal Vin; each of the first and second multi-level comparison device is electrically coupled with the input signal connection point. Here the first and second multi-level comparison devices are the same as the multi-level comparison devices mentioned before in conjunction with FIG. 2 and FIG. 3. In addition, the comparison circuits in the first and second multi-level comparison devices match one another in a one-on-one manner, wherein the matching circuits have their second electrode of the first transistor electrically coupled with the same comparison signal. In other words, the second electrodes of the first transistors in the first multi-level comparison device with fixed power consumption are electrically coupled with one of the second electrodes of the first transistors in the second multi-level comparison device.

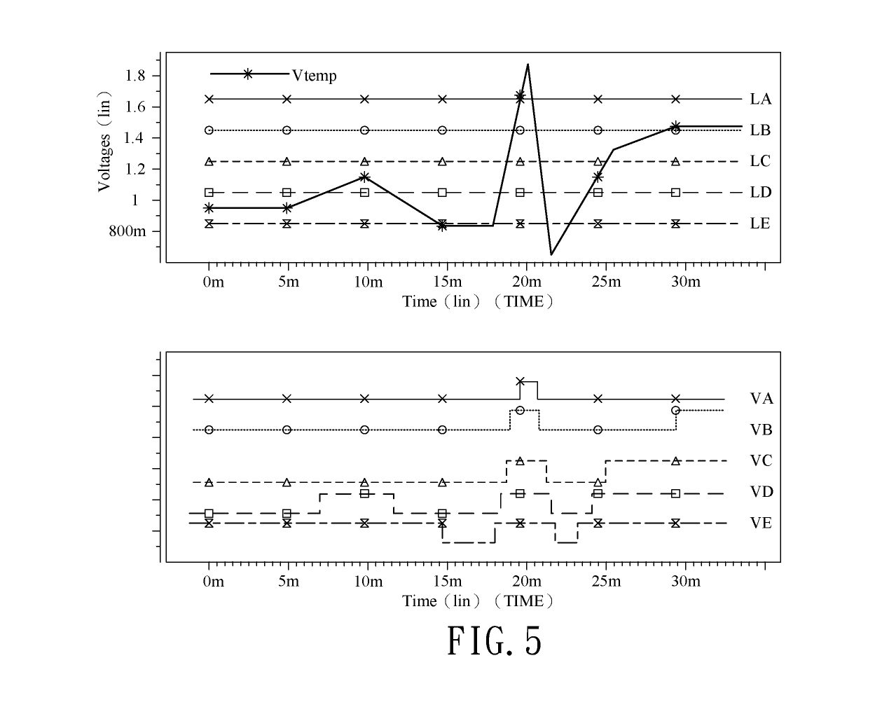

Referring to FIG. 5, which shows the signal simulation results of the present invention in operation. For the purpose of measuring the performance of the disclosed comparator, the experiment is carried out by setting up five different comparison signal levels(VA˜VE) and giving an arbitrary input signal Vin to the disclosed comparator. As shown, when the input signal Vin is lower than the comparison signals, the corresponding output is low; when the input signal Vin is higher than the comparison signals, the corresponding output is high.

The present invention realizes the comparison of multiple level inputs utilizing the analog circuit technique, therefore can meet the design needs such as low power consumption, low voltage, low area, and low noise. The disclosed multi-level comparator is suitable for digital-to-analog or analog-to-digital transformers, power management system, vital sign monitoring system, or any other systems that required multiple comparators.

The foregoing description is not intended to be exhaustive or to limit the invention to the precise forms disclosed. Obvious modifications or variations are possible in light of the above teachings. In this regard, the embodiment or embodiments discussed were chosen and described to provide the best illustration of the principles of the invention and its practical application to thereby enable one of ordinary skill in the art to utilize the invention in various embodiments and with various modifications as are suited to the particular use contemplated. All such modifications and variations are within the scope of the inventions as determined by the appended claims when interpreted in accordance with the breath to which they are fairly and legally entitled.

It is understood that several modifications, changes, and substitutions are intended in the foregoing disclosure and in some instances some features of the invention will be employed without a corresponding use of other features. Accordingly, it is appropriate that the appended claims be construed broadly and in a manner consistent with the scope of the invention.

1. A multi-level comparator with fixed power consumption, comprising:
a first electrical connection point;
a second electrical connection point;
an input circuit, said input circuit being electrically coupled with an input signal;
a plurality of comparison circuits, said input circuit and each said comparison circuit comprising a pair of transistors in series which are a first transistor and a second transistor, respectively, each of said first and second transistor comprising a first electrode, a second electrode, and a third electrode, wherein
for all the series transistors, said third electrode of said first transistor is electrically coupled with said first electrode of said second transistor;
said first electrode of all said first transistors is in parallel with said first electrical connection point;
said third electrode of all said second transistors is in parallel with said second electrical connection point;
said second electrode of said second transistor in all said comparison circuits is in parallel with said third electrode of said first transistor in said input circuit;
said second electrode of said first transistor in each said comparison circuit is electrically coupled with a comparison signal;
said third electrode of said first transistor in each said comparison circuit outputs an output signal; and
said second electrode of said first transistor in said input circuit is electrically coupled with said input signal.

2. The comparator according to claim 1, said third electrode of said first transistor in each said comparison circuit being in series with two inverters for outputting belonging said output signal.

3. The comparator according to claim 1, said first and second transistor being field-effect transistors.

4. The comparator according to claim 1, said first and second transistor being P-channel metal-oxide-semiconductor field-effect transistor(MOSFET) and N-channel metal-oxide-semiconductor field-effect transistor, respectively.

5. The comparator according to claim 4, said first electrical connection point being electrically coupled with a bias circuit, said bias circuit comprising a transistor, said transistor comprising a first electrode, a second electrode and a third electrode, wherein
said first electrode is electrically coupled with a power source;
said second electrode is electrically coupled with a bias signal;
said third electrode is electrically coupled with said first electrical connection point; and
said bias signal controls the bias current between said first and said electrode third electrode.

6. The comparator according to claim 4, said second electrical connection point being electrically coupled with a ground circuit.

7. The comparator according to claim 1, said first and second transistor being a N-type and P-type metal-oxide-semiconductor field-effect transistor(MOSFET), respectively.

8. The comparator according to claim 7, said second electrical connection point being electrically coupled with a bias circuit, said bias circuit comprising a transistor, said transistor comprising a first electrode, a second electrode and a third electrode, wherein
said first electrode is electrically coupled with a ground circuit;
said second electrode is electrically coupled with a bias signal;
said third electrode is electrically coupled with said second electrical connection point; and
said bias signal controls the bias current between said first electrode and said third electrode.

9. The comparator according to claim 7, said first electrical connection point being electrically coupled with a power source.

10. The comparator according to claim 1, each said comparison circuit being electrically coupled with a different said comparison signal.

11. A multi-level comparator with fixed power consumption, comprising:
an input signal connection point, said input signal connection point receiving an input signal; and
a first multi-level comparison device with fixed power consumption and a second multi-level comparison device with fixed power consumption, each of said first and second multi-level comparison device comprising:
a first electrical connection point;
a second electrical connection point;
an input circuit, said input circuit being electrically coupled with said input signal connection point;
a plurality of comparison circuits, said input circuit and each said comparison circuit comprising a pair of transistors in series which are a first transistor and a second transistor, respectively, each of said first and second transistor comprising a first electrode, a second electrode and a third electrode, wherein
for all the series transistors, said third electrode of said first transistor is electrically coupled with said first electrode of said second transistor;
said first electrode of all said first transistors is in parallel with said first electrical connection point;
said third electrode of all said second transistors is in parallel with said second electrical connection point;
said second electrode of said second transistor in all said comparison circuits is in parallel with said third electrode of said first transistor in said input circuit;
said second electrode of said first transistor in each said comparison circuit is electrically coupled with a comparison signal;
said third electrode of said first transistor in each comparison circuit outputs an output signal; and
said second electrode of said first transistor in said input circuit is electrically coupled with said input signal.

12. The comparator according to claim 11, said third electrode of each said first transistor in said first multi-level comparison device with fixed power consumption being in series with two inverters, for outputting belonging said output signal.

13. The comparator according to claim 11, said first and second transistor being field-effect transistors.

14. The comparator according to claim 11, said first and second transistor in said first multi-level comparison device with fixed power consumption being P-channel metal-oxide-semiconductor field-effect transistor(MOSFET) and N-channel metal-oxide-semiconductor field-effect transistor, respectively, said first and second transistor in said second multi-level comparison device with fixed power consumption being N-channel metal-oxide-semiconductor field-effect transistor and P-channel metal-oxide-semiconductor field-effect transistor, respectively.

15. The comparator according to claim 14, said first electrical connection point of said first multi-level comparison device with fixed power consumption being electrically coupled with a bias circuit, said bias circuit comprising a transistor, said transistor comprising a first electrode, a second electrode and a third electrode, wherein
said first electrode is electrically coupled with a power source;
said second electrode is electrically coupled with a bias signal;
said third electrode is electrically coupled with said first electrical connection point; and
said bias signal controls the bias current between said first electrode and said third electrode.

16. The comparator according to claim 14, said second electrical connection point of said first multi-level comparison device with fixed power consumption being electrically coupled with a ground circuit.

17. The comparator according to claim 11, each said comparison circuit of said first multi-level comparison device with fixed power consumption being electrically coupled with a different said comparison signal.

18. The comparator according to claim 14, said second electrical connection point of said second multi-level comparison device with fixed power consumption being electrically coupled with a bias circuit, said bias circuit comprising a transistor, said transistor comprising a first electrode, a second electrode and a third electrode, wherein
said first electrode is electrically coupled with a ground circuit;
said second electrode is electrically coupled with a bias signal;
said third electrode is electrically coupled with said second electrical connection point; and
said bias signal controls the bias current between said first electrode and said third electrode.

19. The comparator according to claim 14, said first electrical connection point of said second multi-level comparison device with fixed power consumption being electrically coupled with a power source.

20. The comparator according to claim 11, said second electrode of said first transistor in said first multi-level comparison device with fixed power consumption being electrically coupled with one of said second electrode of one of said first transistors in said second multi-level comparison device with fixed power consumption.
